(19) United States
(12) Patent Application Publication
(10) Pub. No.: US 2026/0328820 A1
(43) Pub. Date: Oct. 22, 2026

(54) METHODS, SYSTEMS, AND COMPUTER READABLE MEDIA FOR DUAL MIXER TIME DIFFERENCE MEASUREMENT USING SINGLE-BIT SAMPLER

(71) Applicant: Keysight Technologies, Inc., Santa Rosa, CA (US)

(72) Inventor: Arthur Benemann, Thousand Oaks, CA (US)

(21) Appl. No.: 19/181,815

(22) Filed: Apr. 17, 2025

(51) Int. Cl. G01R 25/00

(52) U.S. Cl. CPC G01R 25/005

(57) ABSTRACT

A system for digital dual mixer time difference measurement includes a plurality of single-bit samplers for receiving, as inputs, input signals whose timing is to be compared, and generating, as outputs, sampled binary output signals. The system further includes a transfer oscillator for generating in-phase and quadrature reference signals for mixing with the sampled binary output signals. The system further includes a plurality of mixers for receiving the sampled binary output signals and mixing the sampled binary output signals with the in-phase and quadrature reference signals to produce mixed output signals. The system further includes a plurality of decimation and filter blocks for receiving the mixed output signals and for decimating and filtering the mixed output signals to produce output signals having a lower frequency than the input signals and having a phase difference proportional to a phase difference between the input signals.

### TECHNICAL FIELD

The subject matter described herein relates to quantifying time differences between signals. More particularly, the subject matter described herein relates to methods, systems, and computer readable media for dual mixer time difference measurement using a single-bit sampler.

### BACKGROUND

Dual mixer time difference (DMTD) is a standard method for metrology measurements of oscillators. More generally, DMTD can be used to measure time and frequency differences between signals. One disadvantage of the original DMTD measurement circuits is that they required radio frequency (RF) oscillators, mixers, and filters, which can be bulky, expensive, and can have significant environmental coupling.

In light of the difficulties with RF DMTD measurement circuits, a digital DMTD method developed by the CERN team on a white-rabbit project is an expansion on DMTD. Digital DMTD uses flip-flops as a replacement for the DMTD mixers, effectively implementing down conversion with aliasing through under-sampling. The downside of this implementation is that D-DMTD discards a significant number of the edges of the signal to be measured that occur between samples of the DMTD clock (which does not occur in the original DMTD method), and this increases the noise floor vs. bandwidth of measurement. Another downside of digital DMTD is that using flip-flops inside of an FPGA exposes the signal to be measured to variable propagation delays caused by variations in process, voltage, and temperature (PVT) and increased environmental coupling. Flip-flops implemented in an FPGA fabric also have limited operational frequency, which is typically sub-GHz.

Direct sampling using software defined radio (SDR) to replicate analog DMTD with fast ADCs has been considered by the Naval Research Laboratory in a paper entitled, “A New Digital Phase Measurement System,” 13^{th} Annual Precise Time and Time Interval Meeting, November 2001. Experimental results of using an SDR to replicate an analog DMTD are also reported by the National Institute of Standards and Technology (NIST) in “Oscillator metrology with software defined radio,” Review of Scientific Instruments, 87 054711 (2016) and further extended for time transfer of optical comb clocks in “Quantum-limited optical time transfer for future geosynchronous links,” NIST et al., (2017). One downside with SDR-based DMTD measurement is the use of analog to digital converters (ADCs). which requires extra circuitry and reduces scalability of system.

In light of these and other difficulties, there exists a need for improved methods, systems, and computer readable media for digital DMTD measurements.

### SUMMARY

A system for digital dual mixer time difference measurement includes a plurality of single-bit samplers for receiving, as inputs, input signals whose timing is to be compared, and generating, as outputs, sampled binary output signals. The system further includes a transfer oscillator for generating in-phase and quadrature reference signals for mixing with the sampled binary output signals. The system further includes a plurality of mixers for receiving the sampled binary output signals and mixing the sampled binary output signals with the in-phase and quadrature reference signals to produce mixed output signals. The system further includes a plurality of decimation and filter blocks for receiving the mixed output signals and for decimating and filtering the mixed output signals to produce output signals having a lower frequency than the input signals and having a phase difference proportional to a phase difference between the input signals.

According to another aspect of the subject matter described herein, the single-bit samplers are implemented using a serializer-deserializer (SERDES).

According to another aspect of the subject matter described herein, the SERDES is configured to operate in lock to local reference clock mode. The system of claim 1 wherein the single-bit samplers each comprise a D flip-flop.

According to another aspect of the subject matter described herein, the transfer oscillator comprises a numerically controlled oscillator (NCO).

According to another aspect of the subject matter described herein, the NCO comprises a binary counter connected to an exclusive OR gate for generating the in-phase and quadrature reference signals.

According to another aspect of the subject matter described herein, the mixers each comprise a pair of exclusive OR gates having a first input for receiving the in-phase or the quadrature reference signal and a second input for receiving one of the sampled binary output signals.

According to another aspect of the subject matter described herein, the NCO comprises a lookup table.

According to another aspect of the subject matter described herein, the decimation and filter blocks each include a cascaded integrator comb (CIC) filter and a divide by n counter, n being an integer, for dividing a frequency of one of the mixed output signals.

According to another aspect of the subject matter described herein, the input signals comprise taps of a clock distribution tree.

According to another aspect of the subject matter described herein, a method for digital dual mixer time difference measurement is provided. The method includes receiving, at a plurality of single-bit samplers for receiving, as inputs, input signals whose timing is to be compared, and generating, as outputs, sampled binary output signals. The method further includes generating, using a transfer oscillator, in-phase and quadrature reference signals for mixing with the sampled binary output signals. The method further includes receiving, at a plurality of mixers, the sampled binary output signals and mixing the sampled binary output signals with the in-phase and quadrature reference signals to produce mixed output signals. The method further includes receiving, at a plurality of decimation and filter blocks, the mixed output signals and decimating and filtering the mixed output signals to produce output signals having a lower frequency than the input signals and having a phase difference proportional to a phase difference between the input signals.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a readable computer medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIG. 1 is a block diagram illustrating an exemplary dual mixer time difference measurement circuit including a single-bit sampler;

FIG. 2 illustrates a graph of time interval error (TIE) of signals generated using a DMTD circuit including a single-bit sampler;

FIG. 3 illustrates a graph of time deviation (TDEV) of signals generated using a DMTD circuit including a single-bit sampler;

FIG. 4 illustrates a graph of overlapping Allan deviation (OADEV) of signals generated using a DMTD circuit including a single-bit sampler;

FIG. 5 is a diagram of a DMTD FPGA in which a single-bit sampler is implemented by a pair of D flip-flops;

FIG. 6 is a diagram of a DMTD FPGA in which a transfer oscillator is implemented using a binary counter and an exclusive OR gate;

FIG. 7 is a diagram of a DMTD FPGA in which mixers are each implemented using a pair of exclusive OR gates;

FIG. 8 is a block diagram of a DMTD FPGA in which a decimation and filters block is implemented using CIC filters; and

FIG. 9 is a flow chart illustrating an exemplary process for using a DMTD circuit with a single-bit sampler for time difference measurements.

### DETAILED DESCRIPTION

In one implementation, the subject matter described herein makes use of unused slower speed serializer/deserializer (SERDES) blocks present on these FPGAs to implement a one-bit SDR DMTD system (the highest speed SERDES are typically dedicated to the test interface). This allows for a 500× increase in resolution over off the shelf time to digital converters (TDCs), and a possible >1000 increase in system accuracy, while using subsystems of the FPGA that would otherwise go unused.

The SDR implementation allows for comparison of different clock frequencies, providing an advantage over digital DMTD systems, where clock frequencies being compared must be the same or similar. Bandwidth of the measurement is also defined as post hardware design, providing a tradeoff of bandwidth vs. data throughput.

The subject matter described herein is an extension of the software defined radio-dual mixer time difference implementation. One idea described herein is reducing the ADC to a one-bit device, which allows the system to be used within off-the-shelf FPGAs either via SERDES receivers or flip-flops/latches in the fabric. Using a single-bit sampler instead of a multi-level analog to digital converter allows for high resolution time measurements, specifically with application to (but not limited to) Ethernet timing measurements. In general, the signals input to the single-bit sampler can comprise a tap from a clock distribution tree, such as a clock distribution tree within an ASIC. Here, the term “tap” refers to the tapped signal, rather than the physical piece of equipment that performs the tapping. Tapping a signal in a clock distribution tree may be useful for characterizing phase differences between clock signals at any location in the clock distribution tree.

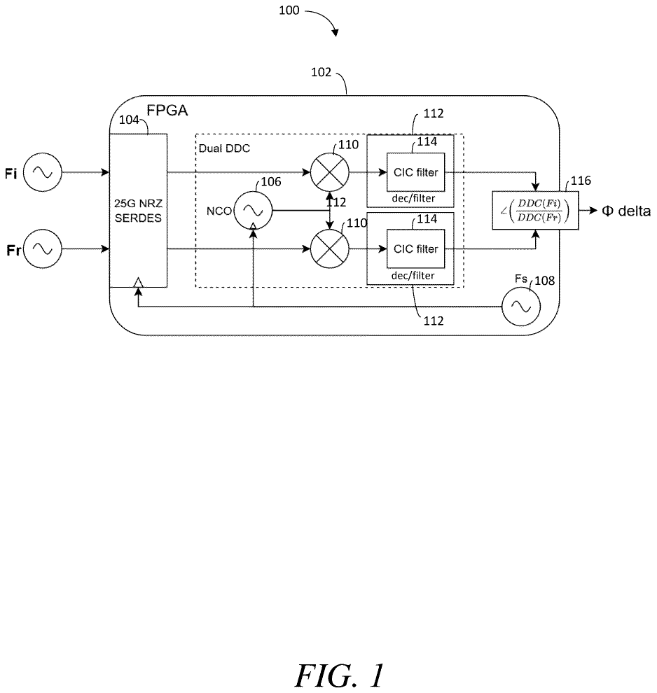

The signal of interest (Fᵢ) and a reference signal (Fᵣ) are sampled with a one-bit ADC, in this case a SERDES receiver running at 25 Gbps, with the clock and data recovery (CDR) unit of the SERDES operating in “lock to local reference clock” mode (which causes the SERDES to sample the signals of interest at sampling clock Fₛ, the reference clock of the SERDES). The signals are then processed with SDR techniques to provide digital down conversion (DDC), DDC results are either processed in system or on an external CPU into phase difference values. This is shown in FIG. 1 for the SERDES acquisition case.

FIG. 1 is a block diagram illustrating an exemplary dual mixer time difference measurement circuit including a single-bit sampler implemented using a SERDES. In FIG. 1, a circuit 100 for digital dual mixer time difference measurement includes an FPGA 102 having a single-bit sampler 104 for receiving, as inputs, input signals whose timing is to be compared, and generating, as outputs, sampled binary output signals. In the illustrated example, single-bit sampler 104 is implemented using a SERDES, such as a 25 gigabit non-return to zero (NRZ) SERDES. In an alternate example, single-bit sampler 104 may be implemented using a data (D) flip-flop.

Digital DMTD measurement circuit 100 further includes a transfer oscillator 106 for generating in-phase and quadrature reference signals for mixing with the sampled binary output signals output from single-bit sampler 104. In the illustrated example, transfer oscillator 106 is a numerically controlled oscillator (NCO) that receives a sampling clock signal generated by a sampling clock oscillator 108. The signal output from transfer oscillator 106 is fed to at least two mixers 110 for receiving the binary output signals output from single-bit sampler 104 and mixing the sampled binary output signals with the in-phase and quadrature reference signals generated by transfer oscillator 106 to produce mixed output signals.

The mixed output signals output from mixers 110 are input to decimation and filter blocks 112. Decimation and filter blocks 112 each include a cascaded interval comb (CIC) filter 114 and a divide by n counter (not shown in FIG. 1). Decimation and filter blocks 112 decimate and filter the mixed output signals output from mixers 110 to produce output signals having a lower frequency than the input signals and having a phase difference proportional to a phase difference between the input signals. A phase difference calculator 116 receives the filtered, decimated output signals output from decimation and filter blocks 112 and generates an output signal that is indicative of the phase difference between the input signal Fᵢ and the reference signal Fᵣ.

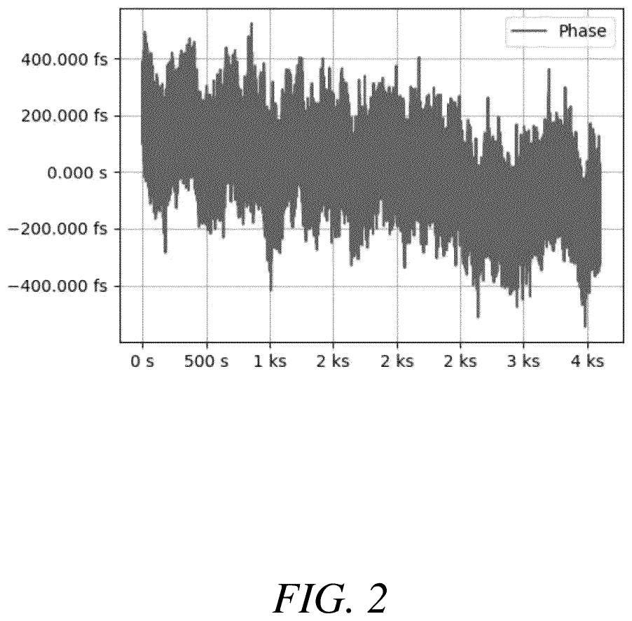

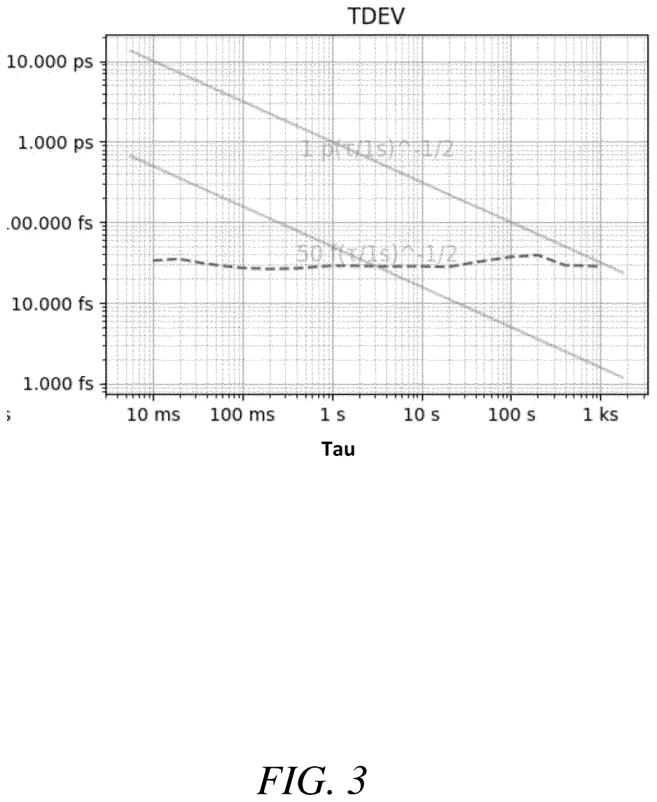

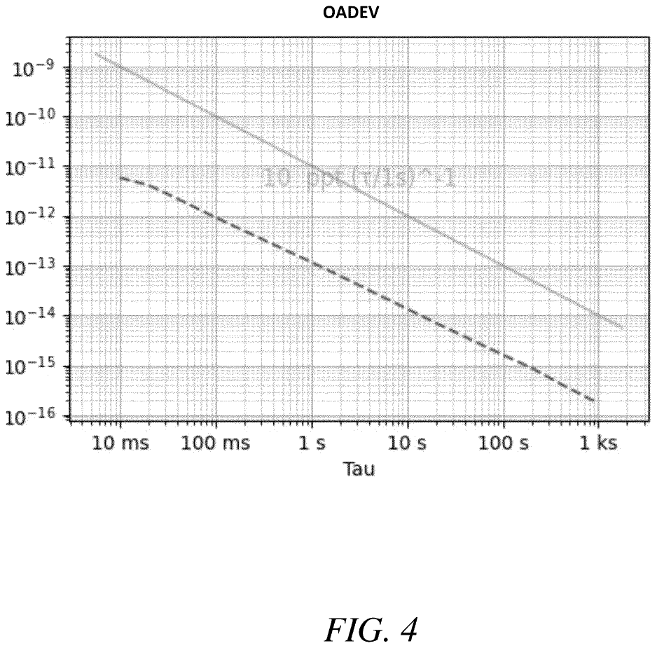

The objective of the signal paths illustrated in FIG. 1 is to reduce the amount of data by filtering incoming signals to only the close in-phase noise of Fᵢ and Fᵣ. Fᵢ and Fᵣ do not need to have similar frequencies, but measuring timing differences when Fᵢ and Fᵣ have different frequencies requires independent locked NCOs (one for each signal whose timing difference is being evaluated). FIGS. 2-4 illustrate results of implementation noise floor time deviation (TDEV) ~30 fs using a VCU129 evaluation board for Xilinx Vertex Ultrascale+FPGAs. FIG. 2 illustrates a graph of time interval error (TIE). FIG. 3 illustrates a graph of time deviation (TDEV), and FIG. 4 illustrates a graph of overlapping Allan deviation (OADEV).

Given some constraints on Fᵢ and Fₛ the dual DDC can be significantly simplified. Examples of such simplifications are as follows and will be described in more detail below.
The NCO can be a short lookup table. For fixed frequency ratios the NCO repeats its output in a fixed pattern, the NCO can be implemented with a lookup table by reading one row at a time for every sample and repeating from the top when list is exhausted.
The mixers can be implemented as XOR logic cells as the input is one-bit, and the NCO can be 1 bit if the correct selection of Fᵢ/Fₛ/Fᵣ/decimation ratio is performed. This optimization requires the NCO output to be ¼ of input frequency. If this is frequency relationship holds, the IQ outputs of the NCO can simplify to the following (1 bit, 4 rows) lookup tables I=0011, and Q=0110. Similarly, for 1/8 ratio between the input and output frequencies of the NCO, a simplification to 2 bits can be performed. If more complex ratios are used the number of bits is larger, and in the irrational ratio case, a different NCO implementation, such as a coordinate rotation digital computer (CORDIC) function, can be used as an approximation.
The CIC filters may follow a standard implementation. However, in the case of a SERDES which provides parallel data output, the NCO, mixer and first stage CIC can all be merged into a single look up table stage. Given the combinational logic implementation of the NCO and the XOR mixers and the parallel nature of SERDES output, for the specific ratios between the NCO input and output frequencies described above, SERDES parallel output can be fed into a two (I and Q) lookup tables to provide result of NCO and XOR functions. Even for ratios that would require more bits (as the ones used during the proof-of-concept experiment 25Gbps/625Mhz=1/40~4 bits), simplifying to a single bit and simple LUT proved sufficient given that the cascaded CIC/decimation filters significantly reduce quantization noise.

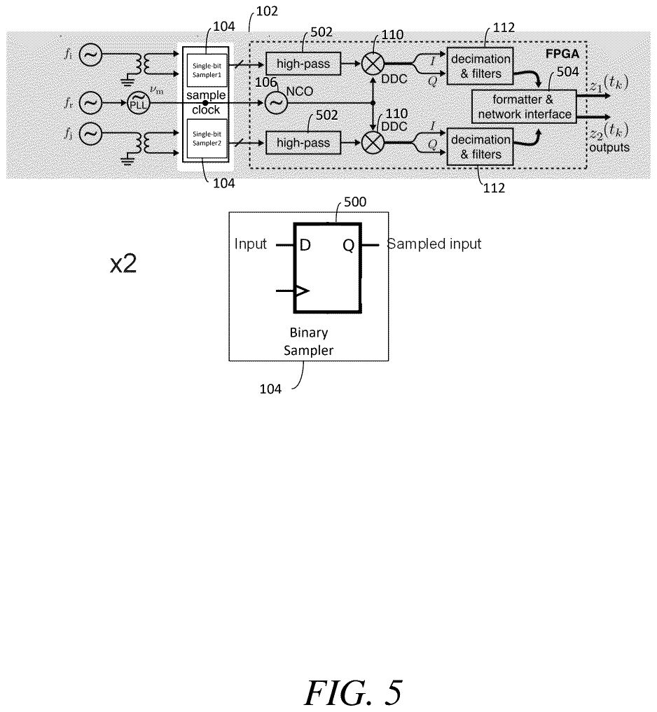

As indicated above, single-bit sampler 104 can be implemented using a SERDES or one or more D flip flops. FIG. 5 is a diagram of FPGA 102 in which single-bit sampler 104 is implemented by a pair of D flip-flops 500. In FIG. 5, each D flip-flop 500 has its data input connected to one of the input signals and its reference input connected to the reference clock. The output of each D flip-flop 500 is provided to a high pass filter 502 before being provided to mixers 110. Decimation and filters blocks 112 decimate and filter the in-phase and quadrature signals output from mixers 110. A formatter and network interface 514 receives the signals output from decimation and filters blocks 112 and generates output signals z₁(tₖ) and z₂(tₖ).

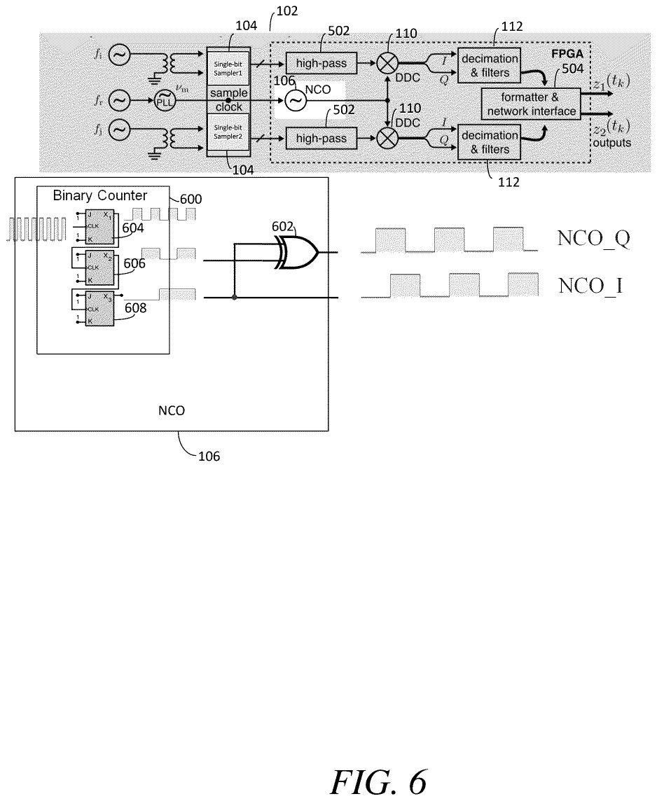

FIG. 6 is a diagram of FPGA 102 where transfer oscillator 106 is implemented using a binary counter 600 and an exclusive OR gate 602. Referring to FIG. 6, binary counter 600 includes a plurality of JK flip-flops 604, 606, and 608. JK flip-flop 604 receives the reference clock signal at its clock input and has its J and K inputs tied high, which makes the noninverted output Q toggle between states. JK flip-flop 606 receives the non-inverted output from JK flip-flop 604 and also has its J and K inputs tied high. JK flip-flop 606 receives the non-inverted output from JK flip-flop 604 and has its J and K inputs tied high. XOR gate 602 is connected to the non-inverted outputs of JK flip flops 606 and 608. The output of XOR gate 602 is the quadrature NCO output and the other noninverted output of JK flip-flop 608 provides the in-phase NCO output signal. The goal of the NCO design illustrated in FIG. 6 is to generate in-phase and quadrature NCO output signals that preserve the frequency difference information between the input signals and to have a frequency that is close to DC.

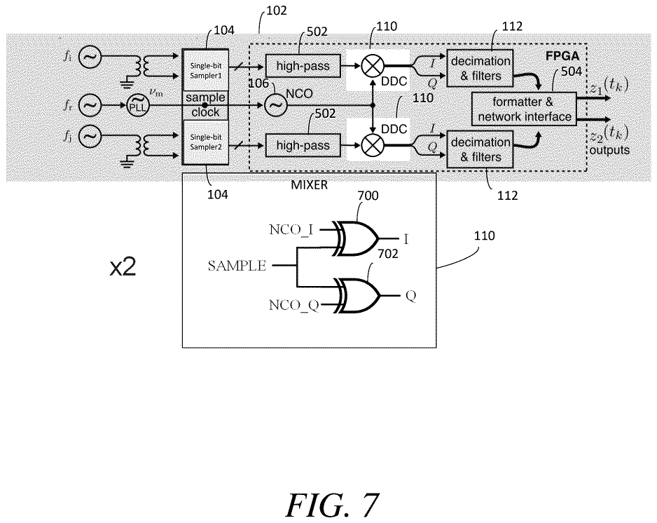

FIG. 7 is a diagram of FPGA 102 in which mixers 110 are each implemented using a pair of exclusive OR gates. In FIG. 7, each mixer 110 includes a pair of exclusive OR gates 700 and 702. Exclusive OR gate 700 receives, at one of its inputs, the in-phase signal output from oscillator 106. Exclusive OR gate 700 receives the sample clock signal at its other input terminal. Exclusive OR gate 700 generates an in-phase output signal at its output terminal. Exclusive OR gate 702 receives, at one of its inputs, the quadrature output signal generated by oscillator 106. Exclusive OR gate 702 receives the sample clock signal at its other input terminal. Exclusive OR gate 702 generates a quadrature output signal at its output terminal.

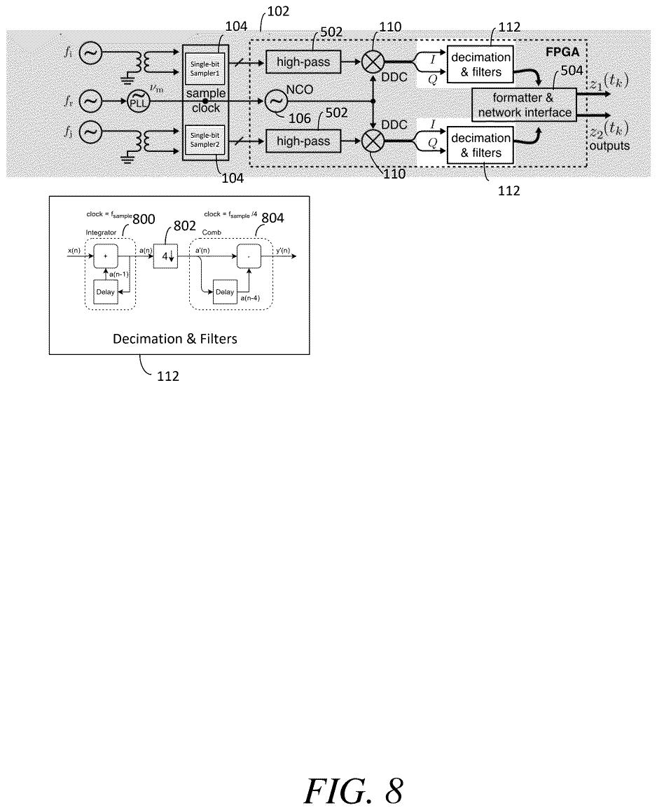

FIG. 8 is a block diagram of FPGA 102 in which decimation and filters blocks 112 are each implemented using CIC filters. In the illustrated example, each decimation and filters block 112 includes a CIC filter that includes an integrator 800, a decimator 802, and a comb filter 804. FIG. 8 also illustrates the moving average filter response of each CIC filter.

Using a low-cost FPGA (such as a Lattice iCE40UP5K) and input/output I/O flip-flops in a fabric implementation, the noise floor of TDEV ~1ps for Tau>1s, while only using a very small section of the FPGA fabric.

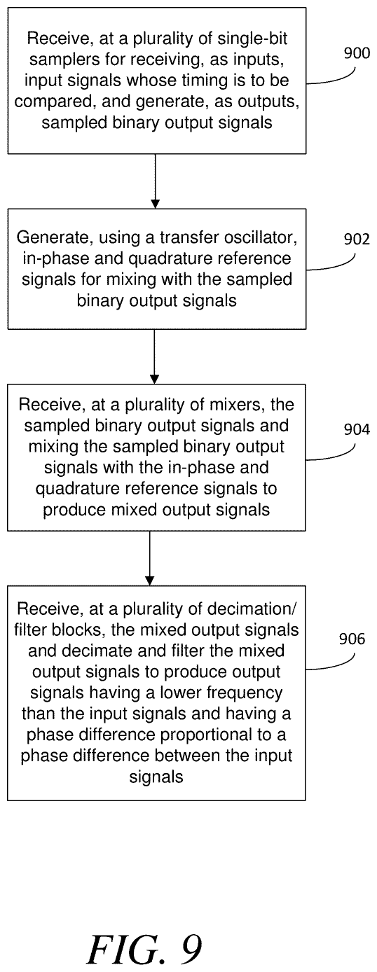

FIG. 9 is a flow chart illustrating an exemplary process for using a DMTD circuit with a single-bit sampler for time difference measurements. Referring to FIG. 9, in step 900, the process includes receiving, at a plurality of single-bit samplers for receiving, as inputs, input signals whose timing is to be compared, and generating, as outputs, sampled binary output signals. For example, single bit samplers 104 may receive one or more input signals whose timing is to be compared.

In step 902, the process further includes generating, using a transfer oscillator, in-phase and quadrature reference signals for mixing with the sampled binary output signals. For example, transfer oscillator 106 may generate in-phase and quadrature reference signals to mix with the sampled input signals.

In step 904, the process further includes receiving, at a plurality of mixers, the sampled binary output signals and mixing the sampled binary output signals with the in-phase and quadrature reference signals to produce mixed output signals. For example, mixers 110 may mix the sampled input signals with the reference signals to produce mixed output signals.

In step 906, the process further includes receiving, at a plurality of decimation and filter blocks, the mixed output signals and decimating and filtering the mixed output signals to produce output signals having a lower frequency than the input signals and having a phase difference proportional to a phase difference between the input signals. For example, decimation and filter blocks 112 may decimate the signals output from mixers 110 to produce output signals of a lower frequency than the input signals and having a phase difference that is proportional to a timing difference between the input signals.

Although in the examples described above, the timing of a single input signal is compared to the timing of a single reference signal, the subject matter described herein is not limited to comparing only two signals. In general, the methodology described herein for comparing timing between signals and a reference signal can be extended to compare the timing of n signals to a reference signal, where n is an integer of at least 2. To extend the architecture to compare n signals to a reference signal, n+1 single-bit samplers, n+1 mixers, a single transfer oscillator, and n+1 decimation and filter blocks may be used. If the frequencies of the signals being compared are different, then n transfer oscillators will be required—one for each input signal with a frequency that is close to the frequency of the input signal.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A system for digital dual mixer time difference measurement, the system comprising:
a plurality of single-bit samplers for receiving, as inputs, input signals whose timing is to be compared, and generating, as outputs, sampled binary output signals;
a transfer oscillator for generating in-phase and quadrature reference signals for mixing with the sampled binary output signals;
a plurality of mixers for receiving the sampled binary output signals and mixing the sampled binary output signals with the in-phase and quadrature reference signals to produce mixed output signals; and
a plurality of decimation and filter blocks for receiving the mixed output signals and for decimating and filtering the mixed output signals to produce output signals having a lower frequency than the input signals and having a phase difference proportional to a phase difference between the input signals.

2. The system of claim 1 wherein the single-bit samplers are implemented using a serializer-deserializer (SERDES).

3. The system of claim 2 wherein the SERDES is configured to operate in lock to local reference clock mode.

4. The system of claim 1 wherein the single-bit samplers each comprise a D flip-flop.

5. The system of claim 1 wherein the transfer oscillator comprises a numerically controlled oscillator (NCO).

6. The system of claim 5 wherein the NCO comprises a binary counter connected to an exclusive OR gate for generating the in-phase and quadrature reference signals.

7. The system of claim 6 wherein the mixers each comprise a pair of exclusive OR gates having a first input for receiving the in-phase or the quadrature reference signal and a second input for receiving one of the sampled binary output signals.

8. The system of claim 5 wherein the NCO comprises a lookup table.

9. The system of claim 1 wherein the decimation and filter blocks each include a cascaded integrator comb (CIC) filter and a divide by n counter, n being an integer, for dividing a frequency of one of the mixed output signals.

10. The system of claim 1 wherein the input signals comprise taps of a clock distribution tree.

11. A method for digital dual mixer time difference measurement, the method comprising:
receiving, at a plurality of single-bit samplers for receiving, as inputs, input signals whose timing is to be compared, and generating, as outputs, sampled binary output signals;
generating, using a transfer oscillator, in-phase and quadrature reference signals for mixing with the sampled binary output signals;
receiving, at a plurality of mixers, the sampled binary output signals and mixing the sampled binary output signals with the in-phase and quadrature reference signals to produce mixed output signals; and
receiving, at a plurality of decimation and filter blocks, the mixed output signals and decimating and filtering the mixed output signals to produce output signals having a lower frequency than the input signals and having a phase difference proportional to a phase difference between the input signals.

12. The method of claim 11 wherein the single-bit samplers are implemented using a serializer-deserializer (SERDES).

13. The method of claim 12 wherein the SERDES is configured to operate in lock to local reference clock mode.

14. The method of claim 11 wherein the single-bit samplers each comprise a D flip-flop.

15. The method of claim 11 wherein the transfer oscillator comprises a numerically controlled oscillator (NCO).

16. The method of claim 15 wherein the NCO comprises a binary counter connected to an exclusive OR gate for generating the in-phase and quadrature reference signals.

17. The method of claim 16 wherein the mixers each comprise a pair of exclusive OR gates having a first input for receiving the in-phase or the quadrature reference signal and a second input for receiving one of the sampled binary output signals.

18. The method of claim 15 wherein the NCO comprises a lookup table.

19. The method of claim 11 wherein the decimation and filter blocks each include a cascaded integrator comb (CIC) filter and a divide by n counter, n being an integer, for dividing a frequency of one of the mixed output signals.

20. The method of claim 11 wherein the input signals comprise taps of a clock distribution tree.
